(19) United States
(12) Patent Application Publication
(10) Pub. No.: US 2026/0223451 A1
(43) Pub. Date: Jul. 30, 2026

(54) SEMICONDUCTOR DEVICE

(71) Applicant: Samsung Electronics Co., Ltd., Suwon-si (KR)

(72) Inventors: Cheoljin Yun, Suwon-si (KR); Daihong Huh, Suwon-si (KR); Dahye Kim, Suwon-si (KR); Sungil Park, Suwon-si (KR)

(21) Appl. No.: 19/300,177

(22) Filed: Aug. 14, 2025

(30) Foreign Application Priority Data
Jan. 24, 2025 (KR) 10-2025-0010905

(51) Int. Cl. H10D 84/85; H10D 84/01

(52) U.S. Cl. CPC H10D 84/856; H10D 84/0167; H10D 84/017; H10D 84/0186; H10D 84/0188; H10D 84/851

(57) ABSTRACT

An embodiment of the present inventive concept provides a semiconductor device. The semiconductor device comprises: lower channel layers; upper channel layers; gate structures; a first source/drain pattern and a second source/drain pattern, wherein the lower channel layers are disposed between the first source/drain pattern and the second source/drain pattern; a third source/drain pattern and a fourth source/drain pattern, wherein the upper channel layers are disposed between the third source/drain pattern and the fourth source/drain pattern; an upper contact structure; a lower contact structure; and a through-contact structure electrically connecting the second source/drain pattern and the fourth source/drain pattern, wherein the gate structures comprise a first gate structure, a second gate structure and a third gate structure, and a first gap between the second gate structure and the third gate structure is greater than a second gap between the first gate structure and the second gate structure.

### CROSS-REFERENCE TO RELATED APPLICATION(S

This application claims benefit of priority under 35 U.S.C. § 119 to Korean Patent Application No. 10-2025-0010905, filed on January 24, 2025, in the Korean Intellectual Property Office, the disclosure of which is incorporated herein by reference in its entirety.

### BACKGROUND

The present inventive concept relates to a semiconductor device.

In accordance with demand for high integration and miniaturization of a semiconductor device, a size of the semiconductor device is also miniaturized. Accordingly, a semiconductor device including a stacked transistor such as a complementary field effect transistor (CFET) stack is being introduced to reduce an area thereof to close to half of an area of a corresponding non-stacked device.

### SUMMARY

An aspect of the present inventive concept is to provide a semiconductor device capable of increasing integration and improving performance.

An aspect of the present inventive concept is to provide a method for forming such a semiconductor device.

According to an aspect of the present inventive concept, a semiconductor device may be provided, comprising: lower channel layers spaced apart from each other in a vertical direction; upper channel layers disposed on the lower channel layers and spaced apart from each other in the vertical direction; gate structures extending in a first direction, intersecting the vertical direction, and surrounding each of the lower channel layers and each of the upper channel layers; a first source/drain pattern and a second source/drain pattern, wherein the lower channel layers are disposed between the first source/drain pattern and the second source/drain pattern and connected to the first source/drain pattern and the second source/drain pattern; a third source/drain pattern and a fourth source/drain pattern, wherein the upper channel layers are disposed between the third source/drain pattern and the fourth source/drain pattern and connected to the third source/drain pattern and the fourth source/drain pattern; an upper contact structure disposed on the third source/drain pattern and connected to the third source/drain pattern; a lower contact structure disposed below the first source/drain pattern and connected to the first source/drain pattern; and a through-contact structure electrically connecting the second source/drain pattern and the fourth source/drain pattern, wherein the gate structures comprise a first gate structure, a second gate structure and a third gate structure, sequentially arranged in a second direction, intersecting the first direction and the vertical direction, and wherein a first gap between the second gate structure and the third gate structure is greater than a second gap between the first gate structure and the second gate structure.

According to an aspect of the present inventive concept, a semiconductor device may be provided, comprising: a first transistor; a second transistor on the first transistor; and a through-contact structure connecting the first transistor and the second transistor, wherein the first transistor comprises: a first source/drain pattern and a second source/drain pattern spaced apart from each other in a first direction; lower channel layers disposed between the first source/drain pattern and the second source/drain pattern and spaced apart from each other in a vertical direction; a plurality of gate electrodes surrounding each of the lower channel layers; and a gate dielectric layer between the plurality of gate electrodes and the lower channel layers, the second transistor comprises: a third source/drain pattern and a fourth source/drain pattern spaced apart from each other in the first direction; upper channel layers disposed between the third source/drain pattern and the fourth source/drain pattern, and spaced apart from each other in the vertical direction; the plurality of gate electrodes surrounding each of the upper channel layers; and the gate dielectric layer between the plurality of gate electrodes and the upper channel layers, wherein the through-contact structure electrically connects the second source/drain pattern and the fourth source/drain pattern, and wherein a side surface of the through-contact structure is spaced apart from an inner side surface of the second source/drain pattern.

According to an aspect of the present inventive concept, a semiconductor device may be provided, a first transistor; a second transistor on the first transistor; a through-contact structure connecting the first transistor and the second transistor; a lower contact structure connected to the first transistor; and an upper contact structure connected to the second transistor, wherein the first transistor comprises: a first source/drain pattern and a second source/drain pattern spaced apart from each other in a first direction; lower channel layers disposed 0between the first source/drain pattern and the second source/drain pattern and spaced apart from each other in a vertical direction; a gate electrode surrounding each of the lower channel layers; and a gate dielectric layer between the gate electrode and the lower channel layers, the second transistor comprises: a third source/drain pattern and a fourth source/drain pattern spaced apart from each other in the first direction; upper channel layers disposed between the third source/drain pattern and the fourth source/drain pattern and spaced apart from each other in the vertical direction; the gate electrode respectively surrounding the upper channel layers; and the gate dielectric layer between the gate electrode and the upper channel layers, the through-contact structure is connected to a first source/drain group including the second source/drain pattern and the fourth source/drain pattern, the upper contact structure and the lower contact structure are connected to a second source/drain group including the first source/drain pattern and the third source/drain pattern, and a length of the first source/drain group in the first direction is about 1.2 to about 2 times a length of the second source/drain group in the first direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to an example embodiment of the present inventive concept;

FIG. 2A is a cross-sectional view taken along line I-I’ of the semiconductor device of FIG. 1;

FIG. 2B is a cross-sectional view taken along line II-II’ of the semiconductor device of FIG. 1;

FIG. 2C is a cross-sectional view taken along line III-III’ region of the semiconductor device of FIG. 2A;

FIGS. 3A and 3B are cross-sectional views illustrating a semiconductor device according to an example embodiment;

FIG. 4 is a cross-sectional view illustrating a semiconductor device according to an example embodiment;

FIGS. 5A and 5B are cross-sectional views illustrating a semiconductor device according to an example embodiment;

FIG. 6 is a cross-sectional view illustrating a semiconductor device according to an example embodiment;

FIG. 7 is a cross-sectional view illustrating a semiconductor device according to an example embodiment; and

FIGS. 8A to 8I are cross-sectional views illustrating according to a process sequence to explain a method of manufacturing a semiconductor device according to example embodiments.

### DETAILED DESCRIPTION

Hereinafter, example embodiments of the present inventive concept will be described with reference to the attached drawings. Unless otherwise specifically stated, in this specification, terms such as “upper,” “an upper surface,” “lower,” “a lower surface,” “a side surface,” and the like are based on the drawings, and may actually vary depending on a direction in which a component is disposed.

In addition, ordinal numbers such as “first,” “second,” “third,” and the like may be used as labels for specific elements, steps, directions, and the like to distinguish various elements, steps, directions, etc. Terms not described using “first,” “second,” etc. in the specification may still be referred to as “first” or “second” in the claims. In addition, terms referenced by a specific ordinal number (e.g., “first” in a particular claim) may be described elsewhere with a different ordinal number (e.g., “second” in the specification or another claim).

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

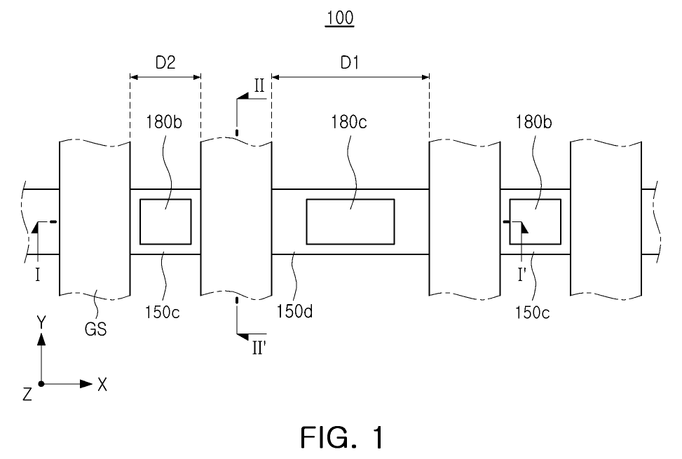

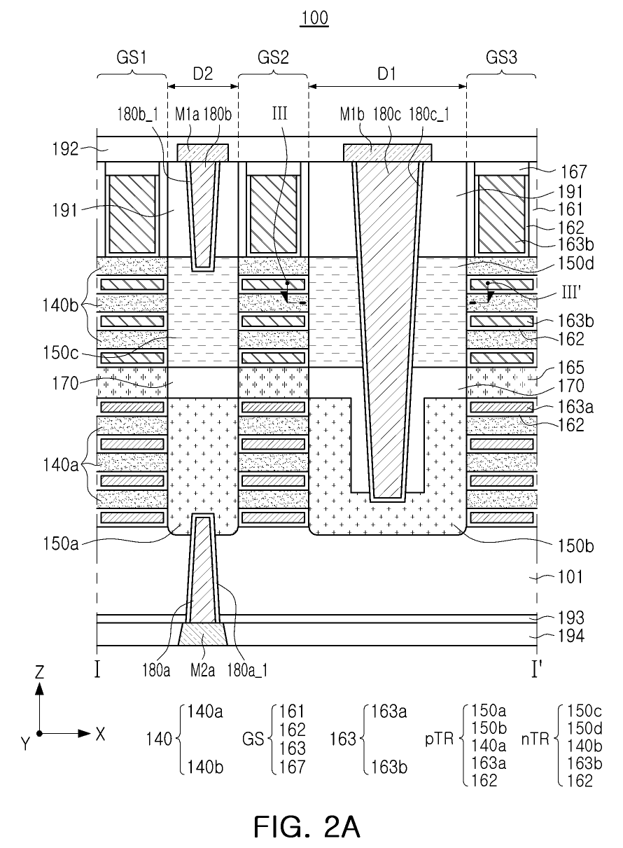

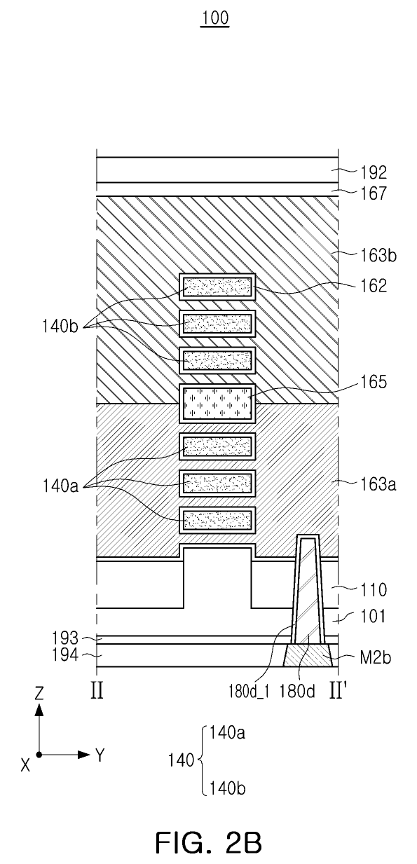

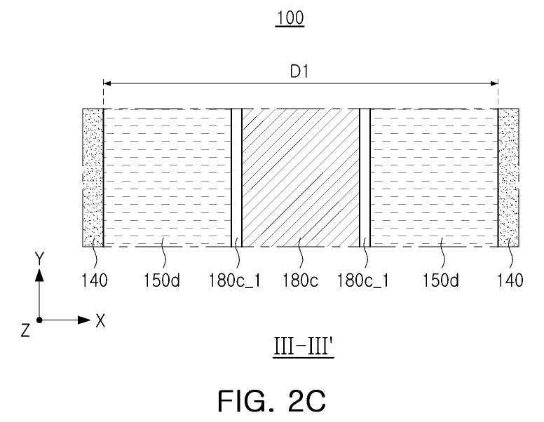

FIG. 1 is a plan view illustrating a semiconductor device according to an example embodiment of the present inventive concept. FIG. 2A is a cross-sectional view taken along line I-I' of the semiconductor device of FIG. 1. FIG. 2B is a cross-sectional view taken along line II-II' of the semiconductor device of FIG. 1. FIG. 2C is a cross-sectional view taken along line III-III' region of the semiconductor device of FIG. 2A.

Referring to FIGS. 1, 2A, 2B and 2C, the semiconductor device 100 may include a first transistor pTR and a second transistor nTR. The first transistor pTR may be a PMOS transistor, and the second transistor nTR may be an NMOS transistor.

The first transistor pTR may include a first source/drain pattern 150a and second source/drain patterns 150b spaced apart from each other, lower channel layers 140a disposed between the first source/drain pattern 150a and the second source/drain pattern 150b and spaced apart from each other in a vertical direction (Z-direction), first gate electrodes 163a surrounding each of the lower channel layers, and a gate dielectric layer 162 between the first gate electrodes 163a and the lower channel layers 140a.

The lower channel layers 140a may include a semiconductor material, such as at least one of silicon, silicon germanium, germanium or silicon carbide.

The first source/drain pattern 150a and the second source/drain pattern 150b may be formed of a semiconductor material having a P-type conductivity. The first source/drain pattern 150a and the second source/drain pattern 150b may be doped with impurities such as a group 13 element of the periodic table, such as B or Al. The first source/drain pattern 150a and the second source/drain pattern 150b may be formed as an epitaxial layer epitaxially grown from a semiconductor body 101 described below. For example, the first source/drain pattern 150a and the second source/drain pattern 150b may include epitaxial silicon germanium.

The second transistor nTR may include a third source/drain pattern 150c and a fourth source/drain pattern 150d spaced apart from each other, upper channel layers 140b disposed between the third source/drain pattern 150c and the fourth source/drain pattern 150d and spaced apart from each other in the vertical direction, second gate electrodes 163b surrounding each of the upper channel layers 140b, and a gate dielectric layer 162 between the second gate electrode 163b and the upper channel layers 140b.

The upper channel layers 140b may include a semiconductor material, such as at least one of silicon, silicon germanium, germanium or silicon carbide. Channel layers 140 may include the lower channel layers 140a and the upper channel layers 140b.

The third source/drain pattern 150c and the fourth source/drain pattern 150d may be formed of a semiconductor material having an N-type conductivity. The third source/drain pattern 150c and the fourth source/drain pattern 150d may be doped with impurities such as a group 15 element of the periodic table, such as P or As. The third source/drain pattern 150c and the fourth source/drain pattern 150d may be formed as an epitaxial layer. Each of the third source/drain pattern 150c and the fourth source/drain pattern 150d may include silicon. In an example, the third source/drain pattern 150c and the fourth source/drain pattern 150d may include epitaxial silicon, and may not include epitaxial silicon germanium.

The semiconductor device 100 may further include a semiconductor body 101 and a device isolation layer 110 under the first transistor pTR. In an embodiment, the semiconductor body 101 may be formed of a semiconductor material. For example, the semiconductor body 101 may include at least one of silicon (Si), silicon germanium (SiGe), germanium (Ge), or silicon carbide (SiC). For example, the semiconductor body 101 may include single crystal silicon. The device isolation layer 110 may be disposed on the semiconductor body 101, and a portion of the semiconductor body 101 may protrude from an upper surface of the device isolation layer 110. For example, the device isolation layer 110 may contact an upper surface of the semiconductor body 101 and side surfaces of the portion of the semiconductor body 101 that protrudes from the upper surface of the device isolation layer 110. The device isolation layer 110 may be formed, for example, by a shallow trench isolation (STI) process. The device isolation layer 110 may include, for example, silicon oxide, silicon nitride, silicon oxynitride or a combination thereof. The device isolation layer 110 may also define an active pattern of the semiconductor body 101.

In another embodiment, the semiconductor body 101 may be replaced with an insulator body. To this end, the semiconductor body 101 may be removed, and an insulating material may be filled in a region in which the semiconductor body 101 was removed. The insulator body may include one of silicon oxide, silicon nitride, silicon oxynitride, silicon oxycarbide and silicon oxycarbonitride. The insulator body may include the same material as at least one of the device isolation layer 110 and a third interlayer insulating layer 193. In this case, a boundary between the insulator body and the device isolation layer 110 or the third interlayer insulating layer 193, having the same material as the insulating body may not be readily identified. Therefore, the insulator body and the device isolation layer 110 may be collectively referred to as a lower insulating layer, or the insulator body and the third interlayer insulating layer 193 may be collectively referred to as a lower insulating layer.

In the present embodiment, the first and second transistors pTR and nTR may be configured to share one gate structure GS.

Referring to FIGS. 2A, 2B and 2C, the first transistor pTR may include lower channel layers 140a stacked on the semiconductor body 101, a first gate electrode 163a surrounding the lower channel layers 140a, a first source/drain pattern 150a and a second source/drain pattern 150b (also referred to as “lower source/drain patterns”) connected to the lower channel layers 140a on one side of the first gate electrode 163a, and a gate dielectric layer 162 between the lower channel layers 140a and the first gate electrode 163a.

Similarly, a second transistor structure TR2 may include upper channel layers 140b, a second gate electrode 163b surrounding the upper channel layers 140b, third source/drain patterns 150c and fourth source/drain patterns 150d (also referred to as “upper source/drain patterns”) connected to the upper channel layers 140b on both sides of the second gate electrode 163b, and a gate dielectric layer 162 between the upper channel layers 140b and the second gate electrode 163b.

The semiconductor device 100 according to the present embodiment may include an isolation insulating layer 170 disposed on the first source/drain pattern 150a to electrically separate the first source/drain pattern 150a and the third source/drain pattern 150c from each other. In addition, the isolation insulating layer 170 may be disposed on the second source/drain pattern 150b to electrically separate the second source/drain pattern 150b and the fourth source/drain pattern 150d from each other. The isolation insulating layer 170 may include, for example, silicon oxide, silicon oxynitride, silicon carbonitride, silicon nitride or a combination thereof.

As described above, the lower channel layers 140a may be spaced apart from and stacked on each other in a vertical direction (e.g., a Z-direction) on a region of the semiconductor body 101. A plurality (for example, three) of the lower channel layers 140a may be provided, each including a semiconductor pattern. For example, the lower channel layers 140a may include at least one of silicon (Si), silicon germanium (SiGe) and germanium (Ge).

Similarly, a plurality (for example, three) of the upper channel layers 140b may be provided in multiples (e.g., three), each including a semiconductor pattern. For example, the upper channel layers 140b may include at least one of silicon (Si), silicon germanium (SiGe), and germanium (Ge).

An intermediate insulating pattern 165 may be disposed on the uppermost lower channel layer of the lower channel layers 140a, and the upper channel layers 140b may be spaced apart from and stacked on each other in the vertical direction (e.g., the Z-direction). The intermediate insulating pattern 165 may be arranged to overlap the lower channel layers 140a and the upper channel layers 140b in the vertical direction (e.g., the Z-direction). As such, the stacked lower channel layers 140a and the stacked upper channel layers 140b may be separated by the intermediate insulating pattern 165.

The intermediate insulating pattern 165 may include an insulating material, and may include at least one of, for example, silicon nitride, silicon oxynitride or silicon carbonitride. The intermediate insulating pattern 165 may be a single insulating material layer, but is not limited thereto, and may include a plurality of insulating material layers.

The first source/drain pattern 150a and the second source/drain pattern 150b may be disposed on both sides of the lower channel layers 140a in a recess portion of the semiconductor body 101. The first source/drain pattern 150a and the second source/drain pattern 150b may be provided as a source region or a drain region of the first transistor pTR. The first source/drain pattern 150a and the second source/drain pattern 150b may be epitaxial layers grown from a surface of the recess portion of the semiconductor body 101 and both side surfaces of the lower channel layers 140a.

Similarly, the third source/drain pattern 150c and the fourth source/drain pattern 150d may be disposed on both sides of the upper channel layers 140b, and may be provided as a source region or a drain region of the second transistor structure TR2. The third source/drain pattern 150c and the fourth source/drain pattern 150d may be epitaxial layers grown using both side surfaces of the upper channel layers 140b as seed layers. The fourth source/drain pattern 150d may have a spaced shape due to partial epitaxial growth. For example, the fourth source/drain pattern 150d may have regions spaced apart in an X-direction.

As a gap between a second gate structure GS2 and a third gate structure GS3 is greater than a gap between a first gate structure GS1 and the second gate structure GS2, the fourth source/drain pattern 150d may not sufficiently grow to completely fill the gap between the second gate structure GS2 and the third gate structure GS3. Accordingly, the fourth source/drain pattern 150d may be divided into two regions spaced apart in an X-direction. A through-contact structure 180c may be disposed between the two spaced regions of the fourth source/drain pattern 150d. On the other hand, the third source/drain pattern 150c may fully grow to completely fill the gap between the first gate structure GS1 and the second gate structure GS2 which have a relatively narrow gap. The first source/drain pattern 150a may also fully grow, similar to the third source/drain pattern 150c.

Similarly, as the gap between the second gate structure GS2 and the third gate structure GS3 is greater than the gap between the first gate structure GS1 and the second gate structure GS2, the second source/drain pattern 150b may not sufficiently grow to completely fill the gap between the second gate structure GS2 and the third gate structure GS3. Accordingly, the second source/drain pattern 150b may be divided into two regions spaced apart in the X-direction, and may have an inner side surface. The second source/drain pattern 150b may include a region grown on the surface of the recess portion of the semiconductor body 101, and the two spaced regions of the second source/drain pattern 150b grown from the lower channel layers 140a and the region grown from the semiconductor body 101 may be connected. Accordingly, the second source/drain pattern 150b may have a ‘U’ shape covering the surface of the recess portion of the semiconductor body 101 and a portion of a side surface of the lower channel layers 140a. The isolation insulating layer 170 and the through-contact structure 180c may be disposed between the two spaced regions of the second source/drain pattern 150b. The isolation insulating layer 170 may be disposed between the second source/drain pattern 150b and the through-contact structure 180c. The isolation insulating layer 170 may overlap the second source/drain pattern 150b in the X-direction. For example, the isolation insulating layer 170 may contact side and upper surfaces the second source/drain pattern 150b. The through-contact structure 180c may overlap the isolation insulating layer 170 in the X-direction between inner side surfaces of the two spaced regions of the second source/drain pattern 150b. For example, the isolation insulating layer 170 may contact side surfaces of the through-contact structure 180c. A side surface of the through-contact structure 180c may be spaced from the inner side surface of the second source/drain pattern 150b.

In the present embodiment, as described above, the first and second transistors pTR and nTR may share one gate structure GS. A gate electrode 163 employed in the present embodiment may be provided as a common gate electrode surrounding upper channel layers 140a and lower channel layers 140b. In addition, the common gate electrode 163 may consist of two or more multi-layers. Accordingly, the gate electrode 163 may include a first gate electrode 163a surrounding the upper channel layers 140a and a second gate electrode surrounding the lower channel layers 140b.

The gate dielectric layer 162 may be provided between the upper channel layers 140a and the gate electrode 163, as well as between the lower channel layers 140b and the gate electrode 163. Similarly, the gate dielectric layer 162 may surround the intermediate insulating pattern 165 in a Y-direction. The gate structure GS may further include gate spacers 161. The gate spacers 161 may be disposed on both sidewalls of an electrode portion extending in the Y-direction on the uppermost upper channel layers 140b of the gate electrode 163. A gate capping layer 167 may be formed on the gate electrode portion between the gate spacers 161.

The gate electrode 163 employed in the present embodiment may include a conductive material. The first gate electrode 163a and the second gate electrode 163b may include different conductive materials, and in some embodiments, may include the same material. The materials included in the first gate electrode 163a and the second gate electrode 163b may vary depending on threshold voltages of the first transistor pTR and the second transistor nTR.

For example, the gate electrode 163 may include at least one of W, Ti, Ta, Mo, TiN, TaN, WN, TiON, TiAlC, TiAlN or TaAlC. The gate electrode 163 may include a semiconductor material such as doped polysilicon.

For example, the gate dielectric layer 162 may include an oxide, a nitride, or a high-κ material, respectively. The high-κ dielectric material refers to a dielectric material having a dielectric constant higher than that of a silicon oxide film (SiO₂), and the high-κ dielectric material may be, for example, any one of aluminum oxide (Al2O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}) and praseodymium oxide (Pr₂O₃).

For example, the gate spacers 161 may include at least one of silicon oxide, silicon nitride or silicon oxynitride. In some embodiments, the gate spacers 161 may include a multilayer structure. The gate capping layer 167 may include, for example, silicon nitride, silicon oxynitride, silicon carbon nitride or silicon oxycarbon nitride.

The gate structure GS may include the first gate structure GS1, the second gate structure GS2 and the third gate structure GS3, disposed in the X-direction. A first gap D1 between the second gate structure GS2 and the third gate structure GS3 may be greater than a second gap D2 between the first gate structure GS1 and the second gate structure GS2. The second gap D2 is in a range of about 1.2 to about 2 times the first gap D1. The first gap of the gate structure GS may be in a range of about 39 nm to about 78 nm.

A width between outer surfaces the fourth source/drain pattern 150d opposing in the X-direction of may be in a range of about 1.2 to about 2 times a width between outer surfaces of the third source/drain pattern 150c opposing in the X-direction, and a width between outer surfaces of the second source/drain pattern 150b opposing in the X-direction may be in a range of about 1.2 to about 2 times a width between the outer surfaces of the first source/drain pattern 150a opposing in the X-direction.

The width between the outer surfaces of the fourth source/drain pattern 150d opposing in the X-direction and the width between the outer surfaces of the second source/drain pattern 150b opposing in the X-direction may be equal to the first gap D1 between the second gate structure GS2 and the third gate structure GS3. The width between the outer surfaces of the third source/drain pattern 150c opposing in the X-direction and the width between the outer surfaces of the first source/drain pattern 150a opposing in the X-direction may be equal to the second gap D2 between the first gate structure GS1 and the second gate structure GS2.

The semiconductor device 100 according to the present embodiment may further include a lower contact structure 180a connected to the first source/drain pattern 150a, an upper contact structure 180b connected to the third source/drain pattern 150c, a through-contact structure 180c connecting the second source/drain pattern 150b and the fourth source/drain pattern 150d, and a gate contact structure 180d connected to the gate electrode 163.

The lower contact structure 180a may be disposed below the first source/drain pattern 150a, and the upper contact structure 180b may be disposed on the third source/drain pattern 150c. In some embodiment, the lower contact structure 180a and the upper contact structure 180b may have a greater length in the Y-direction than the first source/drain pattern 150a and the third source/drain pattern 150c. The lower contact structure 180a and the upper contact structure 180b may be disposed to recess the first source/drain pattern 150a and the third source/drain pattern 150c to a predetermined depth.

The lower contact structure 180a may penetrate at least a portion of the semiconductor body 101 to be in contact with the first source/drain pattern 150a, and may apply an electrical signal to the first source/drain pattern 150a.

The upper contact structure 180b may penetrate at least a portion of first and second interlayer insulating layers 191 and 192 to be in contact with the third source/drain pattern 150c, and may be electrically connected to the third source/drain pattern 150c. The first interlayer insulating layer 191 may contact a side surface of the upper contact structure 180b, and the third source/drain pattern 150c may contact lower side surfaces and a bottom surface of the upper contact structure 180b.

The lower contact structure 180a and the upper contact structure 180b may include metal silicide layers on low ends including lower surfaces thereof, and may further include a lower contact barrier layer 180a_1 and an upper contact barrier layer 180b_1 forming side surfaces of the lower contact structure 180a and the upper contact structure 180b and extending onto upper surfaces of the metal silicide layers, respectively. The lower contact barrier layer 180a_1 and the upper contact barrier layer 180b_1 may contact the side surfaces of the lower contact structure 180a and the upper contact structure 180b and the upper surfaces of the metal silicide layers, respectively. The lower contact barrier layer 180a_1 and the upper contact barrier layer 180b_1 may include, for example, a metal nitride, such as a titanium nitride (TiN) film, a tantalum nitride (TaN) film or a tungsten nitride (WN) film. The lower contact structure 180a and the upper contact structure 180b may include, for example, a metal material, such as, aluminum (Al), tungsten (W) or molybdenum (Mo). In example embodiments, the number and arrangement of conductive layers constituting the lower contact structure 180a and the upper contact structure 180b may be variously changed.

The through-contact structure 180c may connect the first transistor pTR and the second transistor nTR. The through-contact structure 180c may electrically connect the second source/drain pattern 150b and the fourth source/drain pattern 150d.

The through-contact structure 180c may be in contact with an inner side surface of the fourth source/drain pattern 150d. The fourth source/drain pattern 150d may be divided into two regions spaced apart in the X-direction, and the through-contact structure 180c may be disposed between the two spaced regions of the fourth source/drain pattern 150d. The through-contact structure 180c may penetrate the isolation insulating layer 170 and be in contact with the second source/drain pattern 150b.

The through-contact structure 180c may be connected to a first source/drain group including the second source/drain pattern 150b and the fourth source/drain pattern 150d.

The upper contact structure 180b and the lower contact structure 180a may be connected to a second source/drain group including the first source/drain pattern 150a and the third source/drain pattern 150c. A length of the first source/drain group in the X-direction may be about 1.2 to about 2 times a length of the second source/drain group in the X-direction. The through-contact structure 180c may have a similar shape and material to the upper contact structure 180b, but is not limited thereto. The through-contact structure 180c may further include a through-contact barrier layer 180c_1. The through-contact barrier layer 180c_1 may have a similar shape and material to the upper contact barrier layer 180b_1 described above, but is not limited thereto.

The gate contact structure 180d may be in contact with the first gate electrode 163a. For example, the third interlayer insulating layer 193, the semiconductor body 101, and the device isolation layer 110 may contact a side surface of the gate contact structure 180d, and the first gate electrode 163a may contact an upper and side surfaces of the gate contact structure 180d. As another example, the gate contact structure 180d may penetrate the second interlayer insulating layer 192 and the gate capping layer 167 to be in contact with the second gate electrode 163b. The gate contact structure 180d may have a similar shape and material to the lower contact structure 180a and the upper contact structure 180b, but is not limited thereto. The gate contact structure 180d may further include a gate contact barrier layer 180d_1. The gate contact barrier layer 180d_1 may have a similar shape and material to the lower contact barrier layer 180a_1 and the upper contact barrier layer 180b_1 described above, but is not limited thereto.

The first interlayer insulating layer 191 may be disposed on and may contact the third source/drain pattern 150c and the fourth source/drain pattern 150d, and the second interlayer insulating layer 192 may be disposed on and may contact the first interlayer insulating layer 191. The third interlayer insulating layer 193 may be disposed on and may contact the semiconductor body 101, and the fourth interlayer insulating layer 194 may be disposed on and may contact the third interlayer insulating layer 193. The first to fourth interlayer insulating layers 191, 192, 193, and 194 may include, for example, at least one of an oxide, a nitride, an oxynitride, and a low-κ dielectric. The first interlayer insulating layer 191 may be disposed to cover the third source/drain pattern 150c and the fourth source/drain pattern 150d. The second interlayer insulating layer 192 may be disposed to cover the gate structure GS. The third and fourth interlayer insulating layers 193 and 194 may be disposed to cover the semiconductor body 101.

A first interconnection M1 may include a first upper metal interconnection M1a and a second upper metal interconnection M1b, and a second interconnection M2 may include a first lower metal interconnection M2a and a second lower metal interconnection M2b. The first interconnection M1 and the second interconnection M2 may include ruthenium (Ru), molybdenum (Mo), tungsten (W), copper (Cu) or a copper-containing alloy.

The first upper metal interconnection M1a may be electrically connected to the third source/drain pattern 150c through the upper contact structure 180b, and the second upper metal interconnection M1b may be electrically connected to the second source/drain pattern 150b and the fourth source/drain pattern 150d through the through-contact structure 180c. The first lower metal interconnection M2a may be electrically connected to the first source/drain pattern 150a through the lower contact structure 180a, and the second lower metal interconnection M2b may be electrically connected to the first gate electrode 163a through the gate contact structure 180d.

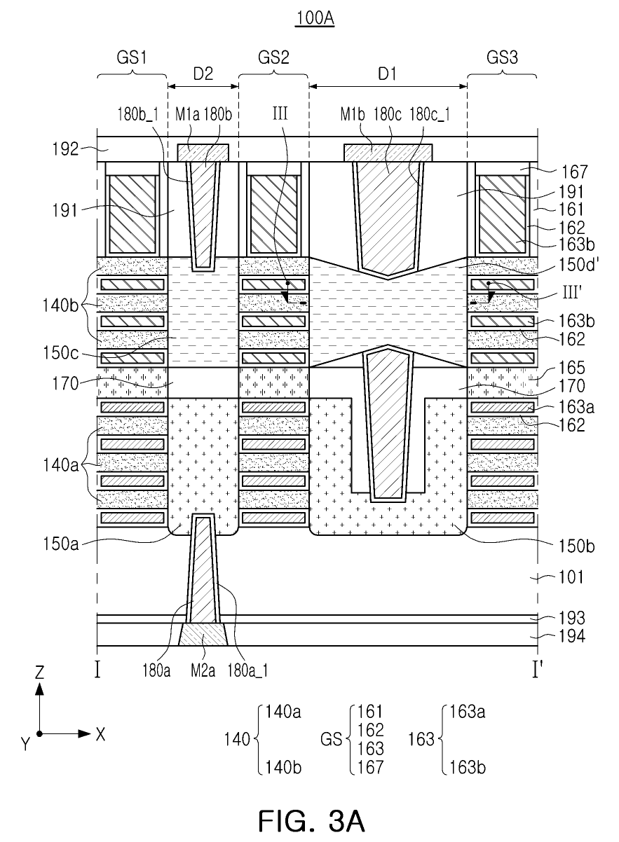

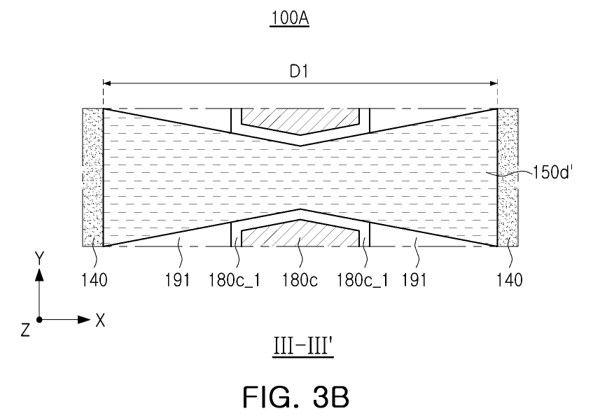

FIGS. 3A and 3B are cross-sectional views illustrating a semiconductor device 100A according to an example embodiment. FIGS. 3A and 3B illustrate regions corresponding to FIGS. 2A and 2C, respectively.

Referring to FIGS. 3A and 3B, it may be appreciated that the semiconductor device 100A is substantially the same as the semiconductor device 100 illustrated in FIGS. 2A to 2C, except that it has a fourth source/drain pattern 150d' of a different shape. In addition, the components of the present embodiment may be understood by referring to the description of the same or similar components of the semiconductor device 100 illustrated in FIGS. 2A to 2C, unless otherwise specifically described.

Unlike the fourth source/drain pattern 150d of FIGS. 2A to 2C, the fourth source/drain pattern 150d' may not have a spaced shape, but may have a shape in which regions grown from the upper channel layers 140b are connected by controlling the epitaxial growth. For example, the fourth source/drain pattern 150d' may have a shape in which two regions grown spaced apart in the X-direction are connected. The fourth source/drain pattern 150d' may have a width in the vertical direction decreasing toward a center of the first gap D1. The fourth source/drain pattern 150d' may have a width in the Y-direction decreasing toward the center of the first gap D1.

The fourth source/drain pattern 150d' may penetrate the through-contact structure 180c in the X-direction. Accordingly, the through-contact structure 180c may surround a portion of the fourth source/drain pattern 150d' in the Z-direction and the Y-direction. A portion of the upper surface, a portion of the side surface and a portion of the lower surface of the fourth source/drain pattern 150d' may be in contact with the through-contact structure 180c. The fourth source/drain pattern 150d' may overlap the through-contact structure 180c in the Y-direction and the Z-direction. The fourth source/drain pattern 150d' may also overlap the through-contact structure 180c in the X-direction.

A portion of the upper surface, a portion of the side surface, and a portion of the lower surface of the fourth source/drain pattern 150d' may be in contact with the first interlayer insulating layer 191.

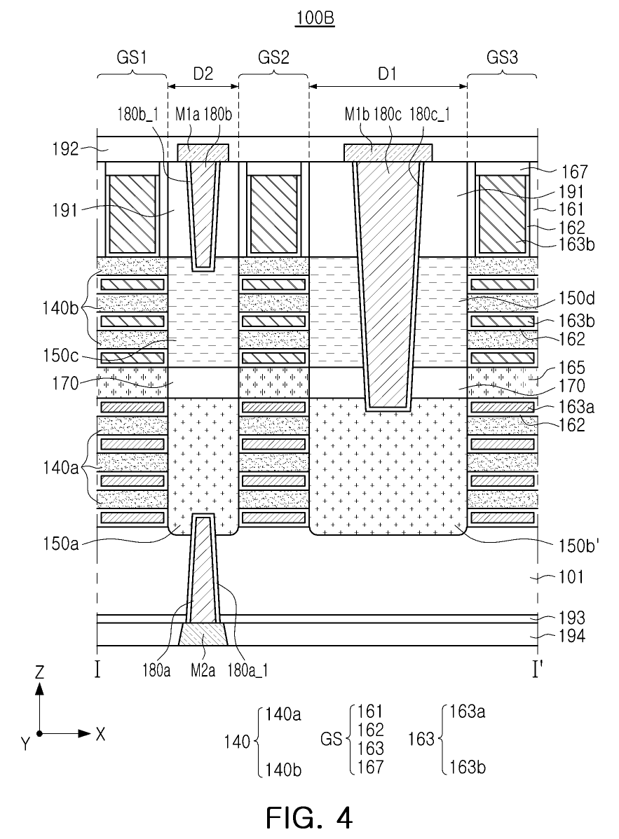

FIG. 4 is a cross-sectional view illustrating a semiconductor device 100B according to an example embodiment. FIG. 4 illustrates an area corresponding to FIG. 2A.

Referring to FIG. 4, it may be appreciated that the semiconductor device 100B according to the present embodiment is substantially the same as the semiconductor device 100 illustrated in FIGS. 2A to 2C, except that it has a second source/drain pattern 150b' of a different shape. In addition, the components of the present embodiment may be understood by referring to the description of the same or similar components of the semiconductor device 100 illustrated in FIGS. 2A to 2C, unless otherwise specifically described.

Unlike the second source/drain pattern 150b of FIG. 2A, the second source/drain pattern 150b' of FIG. 4 may have a form in which an epitaxial layer is completely grown. Accordingly, an upper surface of the second source/drain pattern 150b' may be coplanar with an upper surface of the first source/drain pattern 150a.

Since the second source/drain pattern 150b' does not have a spaced shape, it may not form an inner side surface. The upper surface of the second source/drain pattern 150b' may be in contact with the through-contact structure 180c.

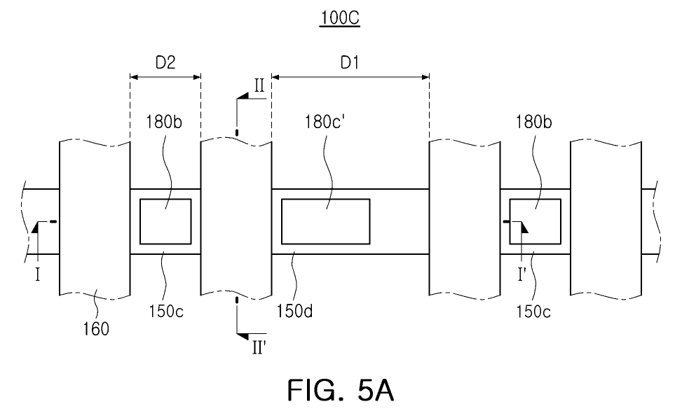

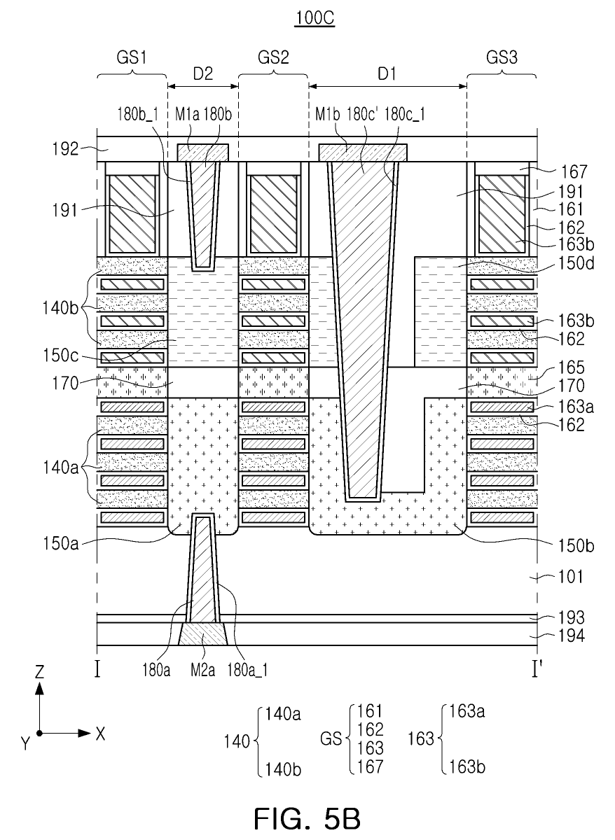

FIGS. 5A and 5B are a plan view and a cross-sectional view illustrating a semiconductor device 100C according to an example embodiment. FIGS. 5A and 5B illustrate regions corresponding to FIGS. 1 and 2A, respectively.

Referring to FIGS. 5A and 5B, it may be appreciated that the semiconductor device 100C according to the present embodiment is substantially the same as the semiconductor device 100 illustrated in FIGS. 1, 2A, 2B and 2C, except that it has a through-contact structure 180c' in a different arrangement. In addition, the components of the present embodiment may be understood by referring to the description of the same or similar components of the semiconductor device 100 illustrated in FIGS. 1, 2A, 2B and 2C, unless otherwise specifically described.

The through-contact structure 180c' of the semiconductor device 100C according to an example embodiment may not be formed at the center of the first gap D1, but may be formed offset to the second gate structure GS2. The through-contact structure 180c' may also be formed offset to the third gate structure GS3, and a position at which the through-contact structure 180c' is arranged may vary depending on embodiments.

The fourth source/drain pattern 150d may be divided into two regions spaced apart in the X-direction, and may have an inner side surface. The first interlayer insulating layer 191 and the through-contact structure 180c may be disposed between the two spaced regions of the fourth source/drain pattern 150d. The first interlayer insulating layer 191 may be disposed between the through-contact structure 180c and the inner side surface of the fourth source/drain pattern 150d. For example, the first interlayer insulating layer 191 may be disposed between the through-contact structure 180c and the fourth source/drain pattern 150d which is not in contact with the through-contact structure 180c. The first interlayer insulating layer 191 may overlap the through-contact structure 180c and the fourth source/drain pattern 150d in the X-direction.

The through-contact structure 180c' may be in contact with a portion of the two spaced regions of the fourth source/drain patterns 150d. The fourth source/drain pattern 150d in contact with the through-contact structure 180c' may be electrically connected to the second source/drain pattern 150b through the through-contact structure 180c'. The fourth source/drain pattern 150d not in contact with the through-contact structure 180c' may be spaced apart from the through-contact structure 180c' through the first interlayer insulating layer 191. The fourth source/drain pattern 150d not in contact with the through-contact structure 180c' may not be electrically connected to the second source/drain pattern 150b.

A transistor including the fourth source/drain pattern 150d not in contact with the through-contact structure 180c' may not be electrically connected to a transistor including the fourth source/drain pattern 150d in contact with the through-contact structure 180c'. A transistor including the fourth source/drain pattern 150d not in contact with the through-contact structure 180c' may not be electrically connected to a transistor including the second source/drain pattern 150b.

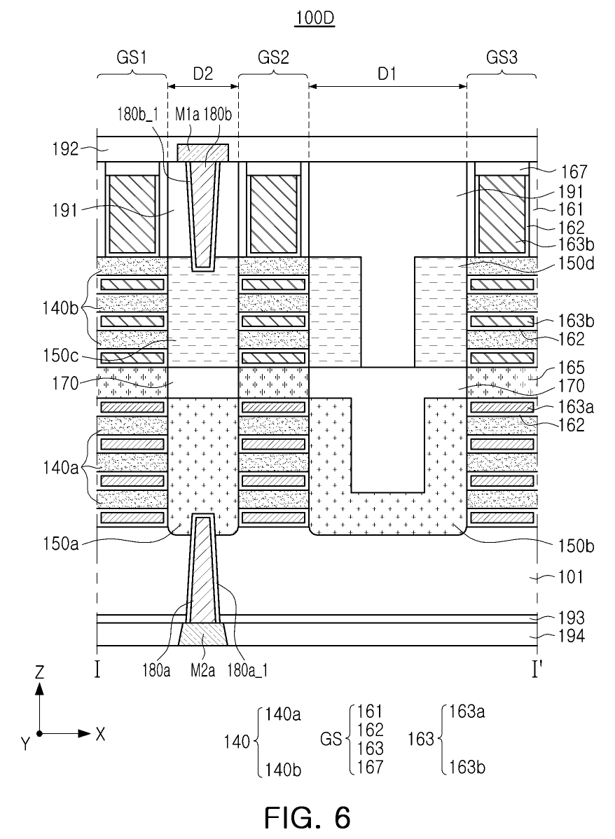

FIG. 6 is a cross-sectional view illustrating a semiconductor device 100D according to an example embodiment. FIG. 6 illustrates an area corresponding to FIG. 2A.

Referring to FIG. 6, it may be appreciated that the semiconductor device 100D according to the present embodiment is substantially the same as the semiconductor device 100 illustrated in FIGS. 2A to 2C, except that it does not include the through-contact structure 180c. In addition, the components of the present embodiment may be understood by referring to the description of the same or similar components of the semiconductor device 100 illustrated in FIGS. 2A to 2C, unless otherwise specifically described.

The semiconductor device 100D according to the example embodiment may not include a through-contact structure. Accordingly, the second source/drain pattern 150b and the fourth source/drain pattern 150d may not be electrically connected. In addition, transistors including the second source/drain pattern 150b may not be electrically connected to transistors including the fourth source/drain pattern 150d.

According to embodiments, the fourth source/drain pattern 150d may have the same shape as the fourth source/drain pattern 150d' of FIG. 3A. Accordingly, the upper transistors may be electrically connected.

According to embodiments, the second source/drain pattern 150b and the fourth source/drain pattern 150d may have fully grown epitaxial layers, and may have a shape of the second source/drain pattern 150b' of FIG. 4.

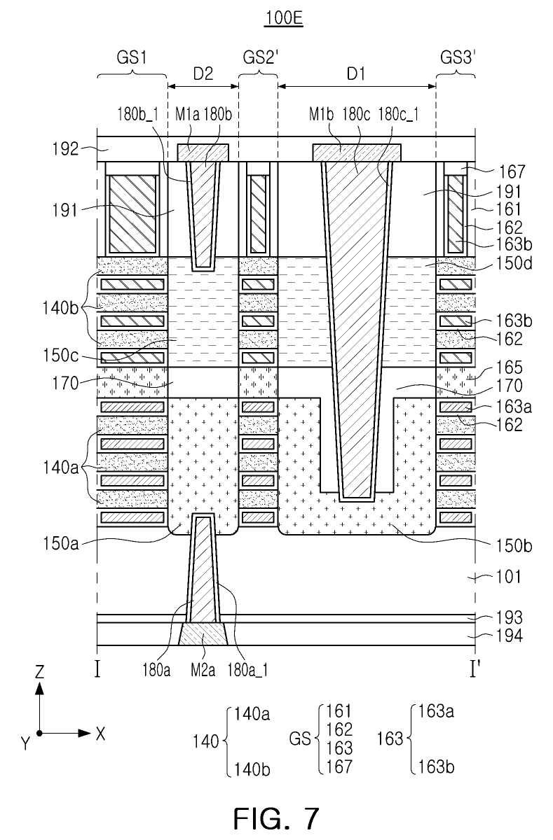

FIG. 7 is a cross-sectional view illustrating a semiconductor device 100E according to an example embodiment. FIG. 7 illustrates an area corresponding to FIG. 2A.

Referring to FIG. 7, it may be appreciated that the semiconductor device 100E according to the present embodiment is substantially the same as the semiconductor device 100 illustrated in FIGS. 2A to 2C, except that widths in the X-direction of a second gate structure GS2' and a third gate structure GS3' are less. In addition, the components of the present embodiment may be understood by referring to the description of the same or similar components of the semiconductor device 100 illustrated in FIGS. 2A to 2C, unless otherwise specifically described.

The widths of the second gate structure GS2' and the third gate structure GS3' may be reduced by means of an etching process. The reduced width in each gate structure may be in a range of about 2 nm to about 3 nm, and the widths in the X-direction of the second gate structure GS2' and the third gate structure GS3' may be less than a width in the X-direction of the first gate structure GS1 by about 2 nm to about 3 nm. Accordingly, a sum of the reduced widths in the X-direction of the second gate structure GS2' and the third gate structure GS3' may be in a range of about 4 nm to about 6 nm.

In an embodiment, the gate structures GS may be arranged in sequence in the X-direction with a second gap. Thereafter, if the widths in the X-direction of the second gate structure GS2' and the third gate structure GS3' are reduced by means of an etching process, a gap between the second gate structure GS2' and the third gate structure GS3' may be increased by an amount of the reduced widths of the second gate structure GS2' and the third gate structure GS3'.

Therefore, a difference between a first gap D1 between the second gate structure GS2' and the third gate structure GS3' and a second gap D2 between the second gate structure GS2' and the first gate structure GS1 may refer to a gate gap increased by means of the etching process. The increased gate gap may be the same as the reduced widths of the second gate structure GS2' and the third gate structure GS3'.

Hereinafter, a method for manufacturing a semiconductor device according to an example embodiment of the present inventive concept will be described.

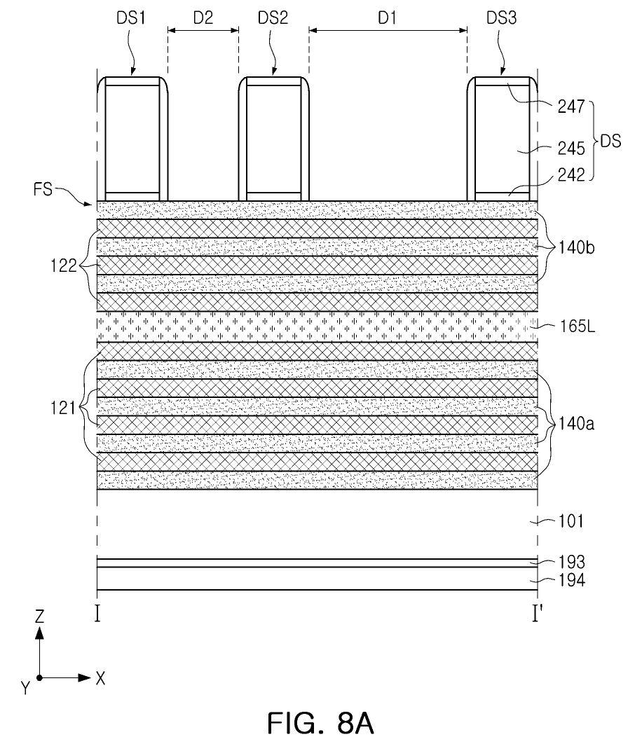

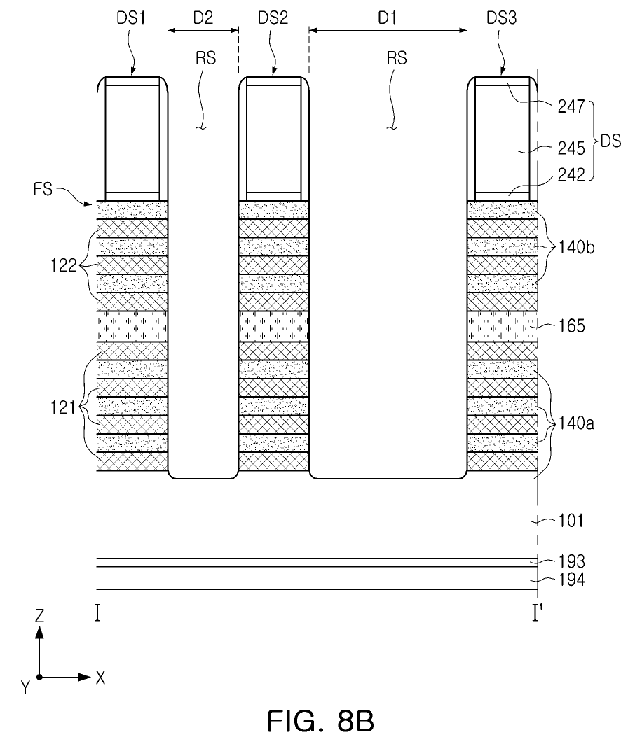

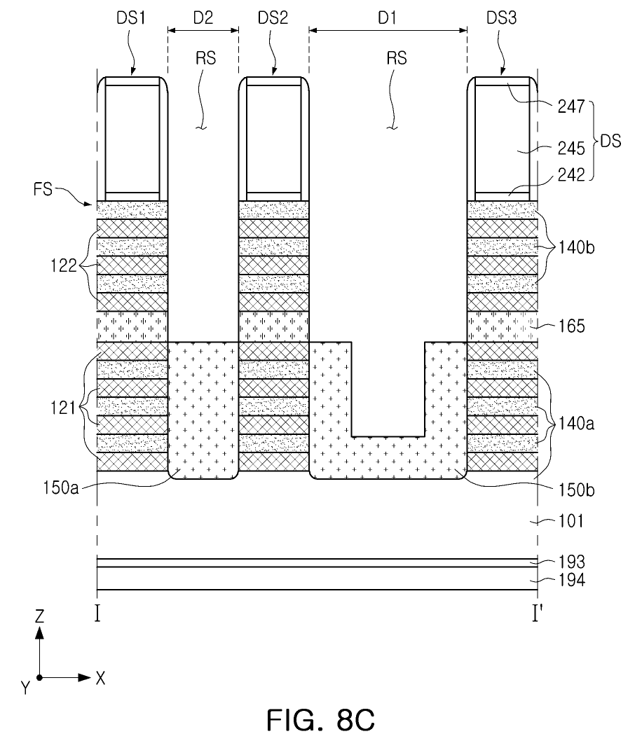

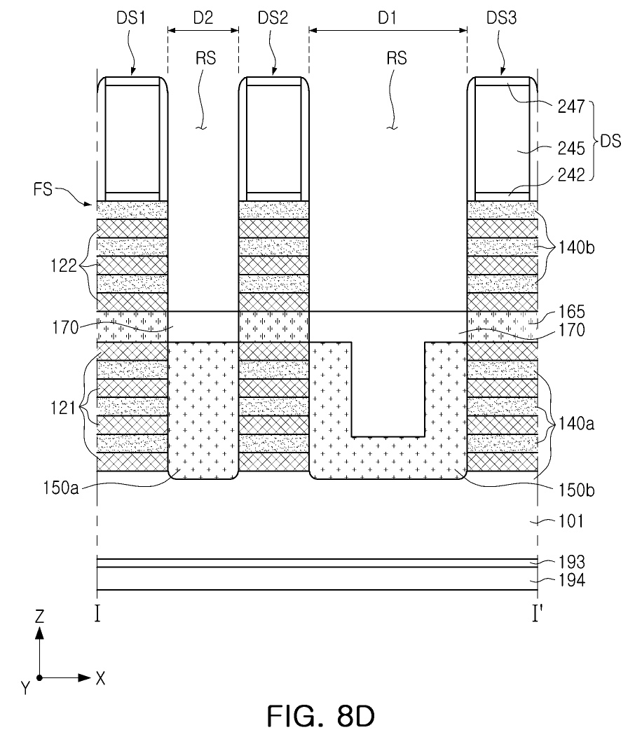

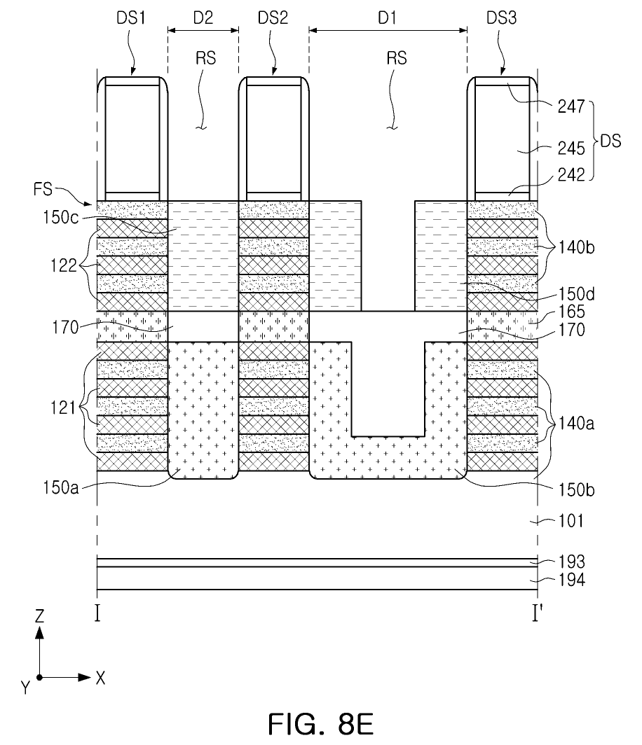

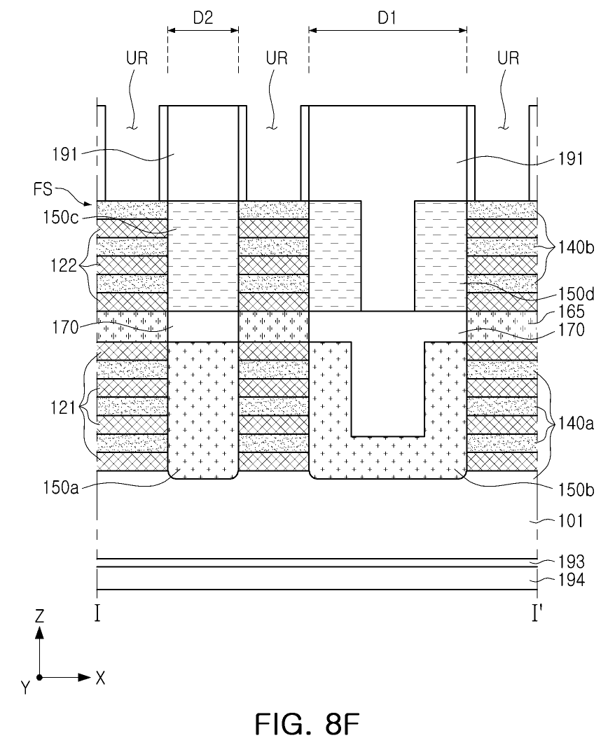

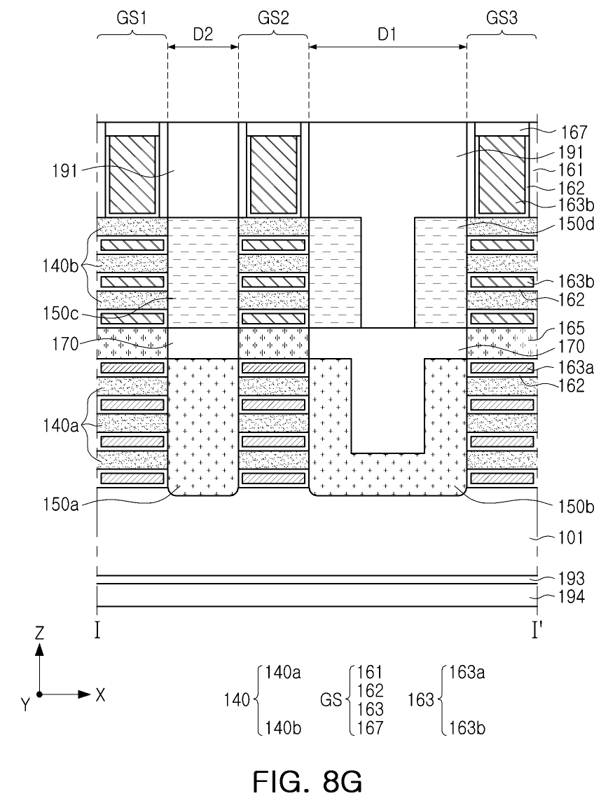

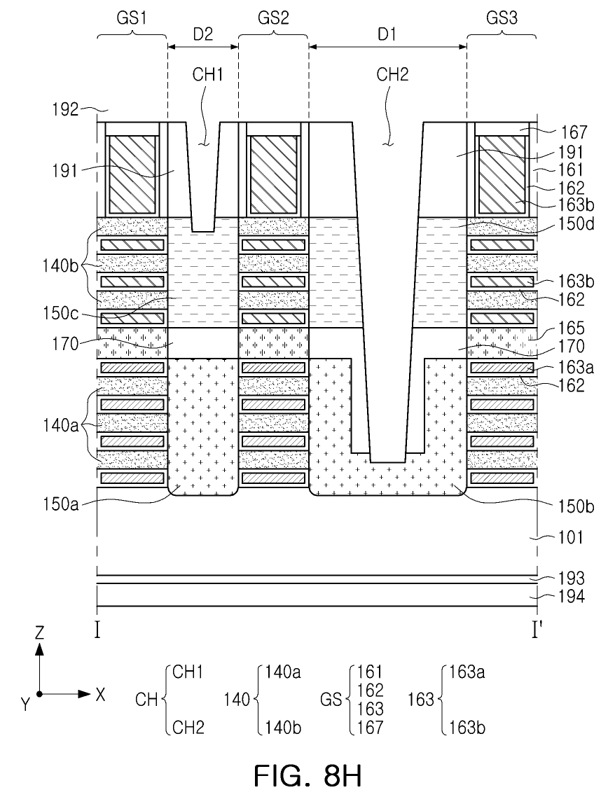

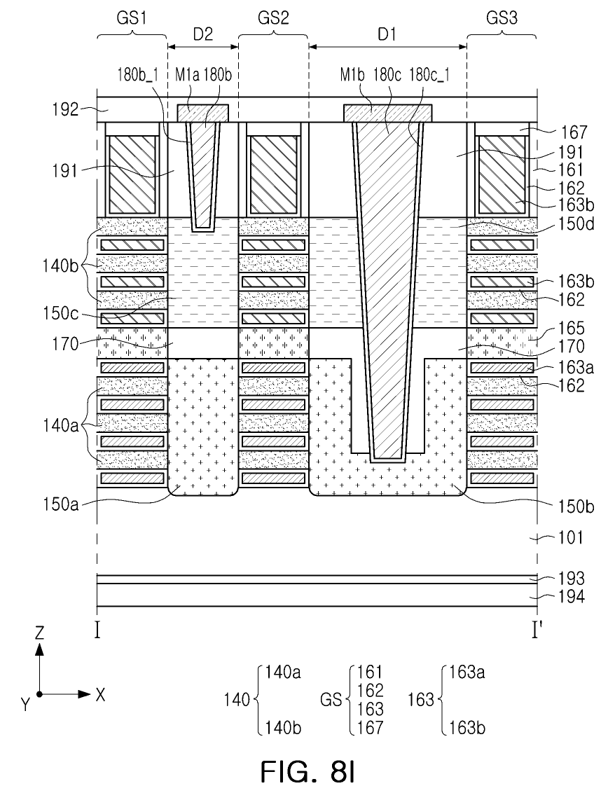

FIGS. 8A to 8I are cross-sectional views illustrating a method of manufacturing a semiconductor device 100 according to example embodiments according to a process sequence. FIGS. 8A to 8I illustrate cross-sections corresponding to FIG. 2A.

Referring to FIG. 8A, a fin-type stacked structure FS may be formed on the semiconductor body 101, and a dummy gate structures DS may be formed on the fin-type stacked structure FS. A third interlayer insulating layer 193 may be formed on a lower surface of the semiconductor body 101, and the fourth interlayer insulating layer 194 may be formed on a lower surface of the third interlayer insulating layer 193.

The fin-type stacked structure FS may be disposed on a semiconductor body 101 extending in the X-direction on the semiconductor body 101, and may include the dummy gate structures DS in the Y-direction to intersect the fin-type stacked structure FS.

The fin-type stacked structure FS may include a first stacked structure in which first sacrificial layers 121 and lower channel layers 140a are alternately stacked, a second stacked structure in which second sacrificial layers 122 and upper channel layers 140b are alternately stacked on the first stacked structure, and an intermediate insulating layer 165L between the first and second stacked structures. The intermediate insulating layer 165L may be provided as an intermediate insulating pattern 165.

The lower channel layers 140a and the upper channel layers 140b may include a semiconductor material for forming a channel of first and second transistors. Each of the lower channel layers 140a and the upper channel layers 140b may include, for example, a semiconductor material including at least one of silicon (Si), silicon germanium (SiGe) or germanium (Ge). The lower channel layers 140a and the upper channel layers 140b may include impurities, but are not limited thereto. The intermediate insulating layer 165L may include at least one of SiO, SiN, SiCN, SiOC, SiON, SiOCN, SiBN or SiBCN.

The first and second sacrificial layers 121 and 122 may include different materials from the upper channel layers 140b and the lower channel layers 140a such that an etchant has etch selectivity with respect to the upper channel layers 140b and the lower channel layers 140a during an etching process. In some embodiments (e.g., when the first and second gate electrodes are formed of different gate electrode materials), the first sacrificial layers 121 may include a different material from the second sacrificial layers 122 such that an etchant has etching selectivity with respect to the second sacrificial layer 122 during an etching process.

For example, the first and second sacrificial layers 121 and 122 may include silicon germanium (SiGe), and the upper channel layers 140b and the lower channel layers 140a may include silicon (Si). The first and second sacrificial layers 121 and 122, the upper channel layers 140b and the lower channel layers 140a may each have a thickness in a range of about 1 to 100 nm. In some embodiments, the number of layers of the upper channel layers 140b and the lower channel layers 140a alternately stacked with the first and second sacrificial layers 121 and 122 may variously changed.

The dummy gate structures DS and gate spacers 141 may be formed on the fin-type stacked structure FS. The dummy gate structures DS may be sacrificial structures providing spaces for forming gate structures GS to be formed in a subsequent process, respectively. The dummy gate structures DS have a line shape extending in the Y-direction intersecting with the fin-type stacked structures FS, and may be arranged spaced apart from each other in the X-direction.

The dummy gate structure DS may include a first dummy gate structure DS1, a second dummy gate structure DS2, and a third dummy gate structure DS3 arranged spaced apart from each other in the X-direction. A first gap between the second dummy gate structure DS2 and the third dummy gate structure DS3 may be greater than a second gap between the second dummy gate structure DS2 and the third dummy gate structure DS3. The second gap may be in a range of about 1.2 to about 2 times the second gap.

In an embodiment, the dummy gate structures DS may have a first gap and a second gap, and may be arranged in the X-direction. In another embodiment, the dummy gate structures DS may be sequentially arranged in the X-direction with a second gap, and a portion of the arrangement of the dummy gate structures DS may be removed to form a gap between the dummy gate structures in the X-direction which is twice the second gap.

The dummy gate structures DS may include first and second dummy material layers 242 and 245 that are sequentially stacked, and a mask pattern layer 247. The first and second dummy material layers 242 and 245 may be patterned using the mask pattern layer 247. The first and second dummy material layers 242 and 245 may be an insulating layer and a conductive layer, respectively, but are not limited thereto, and the first and second dummy material layers 242 and 245 may be formed as a single layer. In some embodiments, the first dummy material layer 242 may include silicon oxide, and the second dummy material layer 245 may include polysilicon. The mask pattern layer 247 may include silicon oxide and/or silicon nitride.

Gate spacers 141 may be formed on both sidewalls of the dummy gate structures DS. The gate spacers 141 may be formed by forming a film of uniform thickness along upper and side surfaces of a substrate on which the dummy gate structures DS are formed, and then anisotropically etching the film. The gate spacers 141 may be made of a low-κ material, and may include, for example, at least one of SiO, SiN, SiCN, SiOC, SiON or SiOCN.

Next, referring to FIG. 8B, the fin-type stacked structure FS exposed between the dummy gate structures DS may be removed to form a recess portion RS.

The recess portion RS may be formed by partially removing portions of the fin-type stacked structure FS between the dummy gate structures DS up to the semiconductor body 101. In this process, it may be performed by removing an exposed region of the fin-type stacked structure FS using the dummy gate structures DS and the gate spacers 141 as a mask. Through such a process, the upper channel layers 140b and the lower channel layers 140b may have a desired length in the X-direction. Portions of the semiconductor body 101 exposed by the recess portion RS and side portions of the lower channel layers 140a may be provided as regions for forming a first source/drain pattern and a second source/drain pattern, and side portions of the upper channel layers 140b may be provided as regions for forming a third source/drain pattern and a fourth source/drain pattern.

Referring to FIG. 8C, a lower source/drain pattern may be formed by forming an epitaxial layer in the recess portion RS. The lower source/drain pattern may include a first source/drain pattern 150a and a second source/drain pattern 150b.

The desired first source/drain pattern 150a and the desired second source/drain pattern 150b may be formed by an epitaxially growth from side surfaces of the lower channel layers 140a and the semiconductor body 101. The second source/drain pattern 150b may have a fully grown form, and an upper surface of the second source/drain pattern 150b may be coplanar with an upper surface of the first source/drain pattern 150a.

The first source/drain pattern 150a and the second source/drain pattern 150b may include silicon germanium doped with a p-type dopant.

Referring to FIG. 8D, an isolation insulating layer 170 may be formed on the lower source/drain pattern in the recess portion RS. The isolation insulating layer 170 may include, for example, silicon oxide, silicon oxynitride, silicon carbonitride, silicon nitride or a combination thereof.

Referring to FIG. 8E, an upper source/drain pattern may be formed by forming an epitaxial layer in the recess portion RS. The upper source/drain pattern may include a third source/drain pattern 150c and a fourth source/drain pattern 150d. The desired third source/drain pattern 150c and the desired fourth source/drain pattern 150d may be formed by an epitaxially growth from side surfaces of the upper channel layers 140b. The fourth source/drain pattern 150d may have a spaced shape as in FIG. 2A or a connected shape as in FIG. 3A.

The third source/drain pattern 150c and the fourth source/drain pattern 150d may include silicon doped with an n-type dopant.

Referring to FIG. 8F, a first interlayer insulating layer 191 may be formed and the dummy gate structure DS may be removed.

The first interlayer insulating layer 191 may be formed by forming an insulating film covering the dummy gate structure DS, the third source/drain pattern 150c, and the fourth source/drain pattern 150d, and then performing a planarization process.

The dummy gate structure DS may be selectively removed with respect to the gate spacers 161, the upper channel layers 140b, and the lower channel layers 140a. Therefore, the dummy gate structure DS may be removed to form upper gap regions UR.

Referring to FIG. 8G, the first and second sacrificial layers 121 and 122 may be removed to form a gate structure GS.

First, the first and second sacrificial layers 121 and 122 may be removed to form lower gap regions (not shown). For example, when the first and second sacrificial layers 121 and 122 include silicon germanium (SiGe) and the upper and lower channel layers 140a, 140b include silicon (Si), the first and second sacrificial layers 121 and 122 may be selectively removed with respect to the upper and lower channel layers 140a and 140b by performing a wet etching process.

The gate structures GS may be formed to fill the upper gap regions UR and the lower gap regions (not shown). The gate dielectric layer 162 may be formed to conformally cover inner surfaces of the upper gap regions UR and the lower gap regions. The gate electrode 163 may be formed to completely fill the upper gap regions UR and the lower gap regions, and then removed from the upper gap regions UR to a predetermined depth together with the gate dielectric layer 162 and the gate spacers 161. As a result, the gate structures GS each including the gate dielectric layer 162, the gate electrode 163, and the gate spacers 161 may be formed.

The gate capping layer 167 may be formed by filling the regions from which the gate electrode 163, the gate dielectric layer 162, and the gate spacers 161 have been removed with an insulating material, and performing a planarization process. A relative thickness of the gate capping layer 167 and a shape of the lower surfaces may be variously changed in embodiments.

Referring to FIG. 8H, contact holes CH may be formed by removing a portion of each of the first interlayer insulating layer 191, the isolation insulating layer 170, the second source/drain pattern 150b, the third source/drain pattern 150c, and the fourth source/drain pattern 150d.

The contact holes CH may include a first contact hole CH1 and a second contact hole CH2.

The first contact hole CH1 may be formed by etching the first interlayer insulating layer 191 from a top in a region where an upper contact structure 180b is to be formed, and recessing the exposed third source/drain pattern 150c from the upper surface thereof.

The second contact hole CH2 may be formed by sequentially etching the first interlayer insulating layer 191 and the isolation insulating layer 170 from a top in a region where a through-contact structure 180c is to be formed, and recessing the exposed second source/drain pattern 150b from an upper surface thereof. The second contact hole CH2 may be formed by recessing a side surface of the fourth source/drain pattern 150d.

The first contact hole CH1 and the second contact hole CH2 may be simultaneously formed by means of one etching process. Due to etching selectivity of the third source/drain pattern 150c, the first interlayer insulating layer 191 and the isolation insulating layer 170, the first interlayer insulating layer 191 and the isolation insulating layer 170 including the oxynitride may be etched relatively deeply while the third source/drain pattern 150c is recessed. Since the fourth source/drain pattern 150d partially forms an epitaxial layer on a side surface of the upper channel layers 140b, the side surface of the fourth source/drain pattern may be exposed during the etching process, and a hole which may reach the second source/drain pattern 150b may be formed. By means of the etching selectivity, the process of forming the first contact hole CH1 for the upper contact structure 180b and the second contact hole CH2 for the through-contact structure 180c may be performed simultaneously, thereby increasing a process efficiency and reducing a process cost.

Referring to FIG. 8I, the upper contact structure 180b, the through-contact structure 180c, and a first interconnection M1 may be formed.

A second interlayer insulating layer 192 covering the first interlayer insulating layer 191 and the gate structure GS may be formed.

The upper contact structure 180b may be formed to penetrate at least a portion of the first and second interlayer insulating layers 191 and 192 and contact the third source/drain pattern 150c.

The through-contact structure 180c may be formed to penetrate at least a portion of the first and second interlayer insulating layers 191 and 192 and at least a portion of the isolation insulating layer 170 and contact the second source/drain pattern 150b.

The first interconnection M1 may include a first upper metal interconnection M1a and a second upper metal interconnection M1b. The first upper metal interconnection M1a may be formed to penetrate at least a portion of the second interlayer insulating layer 192 and contact the upper contact structure 180b, and the second upper metal interconnection M1b may be formed to contact the through-contact structure 180c.

After the above interconnection process, a lower contact structure 180a, a gate contact structure 180d, and a second interconnection M2 may be formed.

A gate contact structure 180d may be formed to penetrate at least a portion of the semiconductor body 101 and contact a first gate electrode 163a.

A fourth interlayer insulating layer 194 may be formed on the semiconductor body 101, and a first lower metal interconnection M2a and a second lower metal interconnection M2b may be formed to contact the lower contact structure 180a and the gate contact structure 180d, respectively, thereby forming the second interconnection M2.

According to embodiments of the present inventive concept, a semiconductor device may have a lower source/drain pattern and an upper source/drain pattern separate from each other and having different conductivity types by disposing an isolation insulating layer between the upper and lower source/drain patterns. As a result, an upper contact structure may contact an upper surface of a third source/drain region, and a lower contact structure may contact a lower surface of a first source/drain pattern, thereby providing a highly integrated semiconductor device.

According to embodiments of the present inventive concept, a semiconductor device may electrically connect an upper transistor and a lower transistor by disposing a through-contact structure.

According to embodiments of the present inventive concept, a contact hole for an upper contact structure and a contact hole for a through-contact structure may be formed by a single etching process while modifying a gap between gate structures.

The various advantageous advantages and effects of the present inventive concept are not limited to the above-described contents, and will be more easily understood in the course of explaining specific embodiments of the present inventive concept.

According to an aspect of the present inventive concept, a method of manufacturing a semiconductor device may be provided, comprising: forming a staked structure including sacrificial layers and upper and lower channel layers on a semiconductor body, and forming a dummy gate structure on the staked structure; removing the staked structure exposed between the dummy gate structure to form a recess portion; forming an epitaxial layer in the recess portion to form a lower source/drain pattern; forming an isolation insulating layer on the lower source/drain pattern in the recess portion; forming an epitaxial layer in the recess portion to form an upper source/drain pattern; forming a first interlayer insulating layer and removing the dummy gate structure; removing the sacrificial layers to form a gate structure; removing a portion of each of the first interlayer insulating layer, the separation insulating layer, the upper source/drain pattern and the lower source/drain pattern to form contact holes; and forming an upper contact structure and a through-contact structure in the contact holes, wherein the dummy gate structures are sequentially arranged with a first gap and a second gap in a first direction, and the first interval is greater than the second interval.

In an embodiment, the first interval may be in a range of about 1.2 to about 2 times the second interval.

In an embodiment, the gate structure may be arranged with a first gap and a second gap in the first direction, and the first interval may be in a range of about 1.2 to about 2 times the second interval.

In an embodiment, the upper source/drain patterns may include silicon doped with an n-type dopant, and the lower source/drain patterns may include silicon germanium doped with a p-type dopant.

In an embodiment, the first gap of the dummy gate structures may be in a range of about 39 nm to about 78 nm.

In an embodiment, the method may further comprise forming a lower contact structure and a gate contact structure in the semiconductor body, and the gate contact structure may penetrate the semiconductor body and be connected to the gate structure.

In an embodiment, the upper source/drain pattern may comprise a third source/drain pattern and a fourth source/drain pattern spaced apart from each other in the first direction, the lower source/drain pattern may include a first source/drain pattern and a second source/drain pattern spaced apart from each other in the first direction, and the through-contact structure may electrically connect the second source/drain pattern and the fourth source/drain pattern.

In an embodiment, the through-contact structure may penetrate the isolation insulating layer and be in contact with the second source/drain pattern.

In an embodiment, the through-contact structure may be in contact with an inner side surface of the fourth source/drain pattern.

In an embodiment, the fourth source/drain patterns may be spaced apart from each other in the first direction, and the through-contact structure may be disposed between the spaced fourth source/drain patterns.

The present inventive concept is not limited to the above-described embodiments and the attached drawings, but is intended to be limited by the appended claims. Accordingly, various forms of substitution, modification, and change may be made by those skilled in the art within the scope that does not depart from the technical idea of the present inventive concept described in the claims, and this will also fall within the scope of the present inventive concept.

What is claimed is:

1. A semiconductor device, comprising:
lower channel layers spaced apart from each other in a vertical direction;
upper channel layers disposed on the lower channel layers and spaced apart from each other in the vertical direction;
gate structures extending in a first direction, intersecting the vertical direction, and surrounding each of the lower channel layers and each of the upper channel layers;
a first source/drain pattern and a second source/drain pattern, wherein the lower channel layers are disposed between the first source/drain pattern and the second source/drain pattern and connected to the first source/drain pattern and the second source/drain pattern;
a third source/drain pattern and a fourth source/drain pattern, wherein the upper channel layers are disposed between the third source/drain pattern and the fourth source/drain pattern and connected to the third source/drain pattern and the fourth source/drain pattern;
an upper contact structure disposed on the third source/drain pattern and connected to the third source/drain pattern;
a lower contact structure disposed below the first source/drain pattern and connected to the first source/drain pattern; and
a through-contact structure electrically connecting the second source/drain pattern and the fourth source/drain pattern,
wherein the gate structures comprise a first gate structure, a second gate structure, and a third gate structure, sequentially arranged in a second direction, intersecting the first direction and the vertical direction, and
wherein a first gap between the second gate structure and the third gate structure is greater than a second gap between the first gate structure and the second gate structure.

2. The semiconductor device of claim 1, wherein the first gap is in a range of about 1.2 to about 2 times the second gap.

3. The semiconductor device of claim 1, wherein the through-contact structure is in contact with an inner side surface of the fourth source/drain pattern.

4. The semiconductor device of claim 1,
wherein the fourth source/drain pattern is divided into two regions spaced apart in the second direction, and
wherein the through-contact structure is disposed between the two regions of the fourth source/drain pattern.

5. The semiconductor device of claim 1, wherein an upper surface of the second source/drain pattern is coplanar with an upper surface of the first source/drain pattern.

6. The semiconductor device of claim 1, further comprising:
an isolation insulating layer on the first and second source/drain patterns,
wherein the through-contact structure penetrates the isolation insulating layer and is in contact with the second source/drain pattern.

7. The semiconductor device of claim 1, wherein the first gap of the gate structures is in a range of about 39 nm to about 78 nm.

8. The semiconductor device of claim 1, wherein a width between outer surfaces of the fourth source/drain pattern opposing in the second direction is in a range of about 1.2 times to about 2 times a width between outer surfaces of the third source/drain pattern opposing in the second direction.

9. The semiconductor device of claim 1,
wherein the first source/drain pattern and the third source/drain pattern have different conductivity types, and
wherein the second source/drain pattern and the fourth source/drain pattern have different conductivity types.

10. The semiconductor device of claim 1, wherein the fourth source/drain pattern has a width in the vertical direction decreasing toward a center of the first gap.

11. The semiconductor device of claim 1,
wherein the fourth source/drain pattern is divided into two regions spaced apart in the second direction, and
wherein the through-contact structure is in contact with a portion of the two regions of the fourth source/drain pattern.

12. A semiconductor device, comprising:
a first transistor;
a second transistor on the first transistor; and
a through-contact structure connecting the first transistor and the second transistor,
wherein the first transistor comprises:
a first source/drain pattern and a second source/drain pattern spaced apart from each other in a first direction;
lower channel layers disposed between the first source/drain pattern and the second source/drain pattern and spaced apart from each other in a vertical direction;
a plurality of gate electrodes surrounding each of the lower channel layers; and
a gate dielectric layer between the plurality of gate electrodes and the lower channel layers,
wherein the second transistor comprises:
a third source/drain pattern and a fourth source/drain pattern spaced apart from each other in the first direction;
upper channel layers disposed between the third source/drain pattern and the fourth source/drain pattern, and spaced apart from each other in the vertical direction;
the plurality of gate electrodes surrounding each of the upper channel layers; and
the gate dielectric layer between the plurality of gate electrodes and the upper channel layers,
wherein the through-contact structure electrically connects the second source/drain pattern and the fourth source/drain pattern, and
wherein a side surface of the through-contact structure is spaced apart from an inner side surface of the second source/drain pattern.

13. The semiconductor device of claim 12, further comprising:
an isolation insulating layer on the first and second source/drain patterns,
wherein the through-contact structure penetrates the isolation insulating layer and is in contact with the second source/drain pattern.

14. The semiconductor device of claim 12,
wherein the third and fourth source/drain patterns include silicon doped with an n-type dopant, and
the first and second source/drain patterns include silicon germanium doped with a p-type dopant.

15. The semiconductor device of claim 12, further comprising:
an upper contact structure disposed on the third source/drain pattern and connected to the third source/drain pattern; and
a lower contact structure disposed below the first source/drain pattern and connected to the first source/drain pattern.

16. The semiconductor device of claim 12, wherein the plurality of gate electrodes are disposed to form first and second gaps in the first direction, and the first gap is about 1.2 times to about 2 times the second gap.

17. The semiconductor device of claim 16, wherein the through-contact structure is formed between the plurality of gate electrodes forming the first gap.

18. The semiconductor device of claim 12, wherein a width between outer surfaces of the second source/drain pattern opposing in the first direction is in a range of about 1.2 times to about 2 times a width between outer surfaces of the first source/drain pattern opposing in the first direction.

19. A semiconductor device, comprising:
a first transistor;
a second transistor on the first transistor;
a through-contact structure connecting the first transistor and the second transistor;
a lower contact structure connected to the first transistor; and
an upper contact structure connected to the second transistor,
wherein the first transistor comprises:
a first source/drain pattern and a second source/drain pattern spaced apart from each other in a first direction;
lower channel layers disposed between the first source/drain pattern and the second source/drain pattern and spaced apart from each other in a vertical direction;
a gate electrode surrounding each of the lower channel layers; and
a gate dielectric layer between the gate electrode and the lower channel layers,
wherein the second transistor comprises:
a third source/drain pattern and a fourth source/drain pattern spaced apart from each other in the first direction;
upper channel layers disposed between the third source/drain pattern and the fourth source/drain pattern and spaced apart from each other in the vertical direction;
the gate electrode respectively surrounding the upper channel layers; and
the gate dielectric layer between the gate electrode and the upper channel layers,
wherein the through-contact structure is connected to a first source/drain group including the second source/drain pattern and the fourth source/drain pattern,
wherein the upper contact structure and the lower contact structure are connected to a second source/drain group including the first source/drain pattern and the third source/drain pattern, and
wherein a length of the first source/drain group in the first direction is about 1.2 to about 2 times a length of the second source/drain group in the first direction.

20. The semiconductor device of claim 19,
wherein the third and fourth source/drain patterns include silicon doped with an n-type dopant, and
wherein the first and second source/drain patterns include silicon germanium doped with a p-type dopant.
